(19) United States
(12) Patent Application Publication
(10) Pub. No.: US 2013/0002095 A1
(43) Pub. Date: Jan. 3, 2013

(54) BENDING TRANSDUCER

(75) Inventor: Klaus Van Der Linden, Redwitz (DE)

(73) Assignee: JOHNSON MATTHEY CATALYSTS (GERMANY) GMBH, Redwitz (DE)

(21) Appl. No.: 13/583,997

(22) PCT Filed: Mar. 10, 2011
(86) PCT No.: PCT/EP2011/001191

§ 371 Date: Sep. 11, 2012

(30) Foreign Application Priority Data
Mar. 11, 2010 (DE) 10 2010 011 047.7

(51) Int. Cl. H01L 41/04

(52) U.S. Cl. 310/340

(57) ABSTRACT

The bending transducer has a layer construction containing a piezoelectrically active element, which is formed of a piezoactive material, in particular a piezoceramic, and electrode layers fitted thereon. In order to enable a high bending loading of the bending transducer and to reduce the risk of fracture, it is provided that a protective layer is applied to the layer construction on the outer side, preferably on both sides, which protective layer is applied to the layer construction in particular under prestress.

The invention relates to a bending transducer having a layer construction, comprising a piezoelectrically active element, consisting of a piezoactive material and electrode layers applied thereon.

Piezoelectric bending transducers generally take advantage of the piezoelectric effect in order to convert a mechanical deformation of the piezoactive material into an electric signal and vice versa. Bending transducers are therefore used both in the fields of sensor systems, such as pressure sensors, and actuator systems, for example as actuating elements. The use of bending transducers as generators for generating electric energy is additionally known, for example from DE 10 2008 007 774 A1. A field where this energy generation using piezoceramic, also referred to as energy harvesting, is used, is, for example, the power supply of a transmitter for wireless transmission of a measurement signal, such as a pressure signal from a tire pressure sensor arranged in a tire to a receiver located outside the tire.

In order to utilize the piezoelectric effect, electrical contacting of the piezoactive material is necessary. This occurs via “electrode layers,” which are applied on both sides on the piezoactive material. The electrode layers are generally continuous layers but can also have structuring.

A piezoelectrically active element formed from such a layer construction is often applied on a mechanical carrier. If only one piezoelectrically active element, that is to say a piezoactive material having electrode layers applied thereon, is applied on one side on such a mechanical carrier, the result is what is called a monomorph bending transducer. If such a piezoelectrically active element is applied on both sides on the mechanical carrier, the result is called a trimorph bending transducer. A bimorph bending transducer refers to the bonding together of two piezoelectrically active elements without a mechanical carrier. The two bonded piezoelectrically active elements here share a common electrode layer. In a multimorph construction, typically more than two piezoelectrically active elements are bonded in layers.

The piezoactive material typically used is a piezoceramic, in particular what is called a PZT ceramic (lead-zirconate-titanium).

In principle, as high a mechanical bending or deformation of the bending transducer as possible is desired in order to generate as large an electric signal as possible, in particular when used to generate energy. This is opposed by the very brittle material characteristic of the piezoactive material. In general terms, in order to avoid damage, such as for example breaking of the piezoactive material, a piezoceramic may be loaded to at most approximately 1% for strain and approximately at most 1% for pressure. This means that a relative extension ΔL/L for a strain (stretching) can be at most 0.001 and for a pressure load (compression) at most 0.01. Loads that exceed this can result in a destruction of the piezoceramic. It should be taken into account here that the layers of the piezoactive material (piezoceramic) are extremely thin and for example have a layer thickness ranging from only 50 to 400 μm. The piezoceramic layer is therefore an extremely thin and brittle film. For simpler handling during the production, DE 33 10 589 A1 makes provision for the piezoceramic being impregnated with a synthetic resin before the electrode layers are applied and for the synthetic resin subsequently being cured to a thermosetting plastic.

The invention is based on the object of specifying a bending transducer with an improved load capacity. The object is achieved according to the invention by a bending transducer having a layer construction, comprising a piezoelectrically active element, consisting of a piezoactive material and electrode layers applied thereon, wherein the layer construction has a protective layer on the outside. The protective layer is applied in a suitable manner on the layer construction or if appropriate on the piezoactive material, in particular with an adhesive layer in the manner of a laminate. The protective layer is in particular electrically functionless, that is to say is preferably non-conductive, but can itself be a carrier layer for conductor tracks or conductive layers. On the outside means in this case the uppermost or lowermost layer (exterior flat face) of the layer construction that is usually formed by an electrode layer.

Investigations have shown that bending transducers that have been provided with an elastic protective layer of this type have a load capacity, both for the strain load and for the pressure load, that is higher by a factor of 10 when compared to an embodiment variant without an elastic protective layer.

Overall, the bending transducer is thus formed in the manner of a laminate, consisting of the layer construction and the elastic protective layer applied on the outside of the layer construction.

According to one preferred configuration, the protective layer is applied onto the layer construction, that is to say onto the outermost layer of the layer construction, under a prestress. The connection between the protective layer and the layer construction is therefore not stress-free. Rather, the protective layer exerts a prestress, preferably a pressure load, in the connection plane with the layer construction. Premature failure or breaking of the layer construction under a (bending) load is thus effectively counteracted by said prestress, which is, as it were, exerted from the outside.

The prestress here has in particular no preferential direction. However, it can be deliberately orientated in one direction, preferably in the longitudinal direction of the bending transducer such that the prestress is orientated in the same direction as the compressive stresses occurring during bending.

The prestress is produced when the protective layer is applied onto the layer construction. Depending on the type of protective layer, various possibilities are open for this. In the case of an elastic protective layer, the prestress is achieved, for example, by pre-stretching the protective layer, which is applied in the pre-stretched state such that the elastic restoring force exerts the prestress. Alternatively, the protective layer is applied using a curable substance, for example in the form of what is called a prepreg or as a varnish. Preferably, the substance and/or the process parameters for the application of the substance is selected such that the prestress is produced during curing, in particular by a shrinking process. If the layer construction also undergoes a change in length on account of the selected production process, the shrinkage of the applied protective layer is greater than that of the layer construction. The prestress is in this case produced in particular by a thermal process, that is to say by a heat treatment with subsequent cooling. For example, the protective layer is heated before being bonded to the layer construction, subsequently bonded thereto, for example adhesively, in order to cool in the bonded state.

According to one preferred embodiment, provision is made for the protective layer to have a coefficient of thermal expansion that is different, preferably greater, than that of the layer construction, in particular as its outermost layer, in order to reliably produce a thermal prestress.

According to one preferred development, the protective layer has, in addition or alternatively to the prestress, a higher elasticity and/or a higher modulus of elasticity than the layer construction, in particular than the piezoactive material. As a result, the risk of breaking is further reduced. Higher elasticity in this case means that the material of the elastic protective layer has an in particular distinctly higher yield strength or yield stress. Yield stress is generally understood to mean that stress in a stress-strain curve, up to which the material shows only elastic deformation but no plastic deformation. Modulus of elasticity E generally refers to the quotient between the stress and the elongation in the linear elastic region in the stress-strain curve. The modulus of elasticity thus gives the (constant) gradient in the linear elastic region in the curve.

The thickness of the protective layer is preferably greater than 50 μm, preferably greater than 100 μm, and is in particular in the range of up to approximately 1000 μm. The thickness of the protective layer is in particular greater than the thickness of the respective electrode layer. The thickness of the electrode layers for example when using gold electrodes lies in the region of a few 100 nm, and when using what are called carbon electrodes, the thickness ranges for example from 5 to 50 μm. The thickness of the piezoactive material itself ranges for example from 50 to 400 μm.

According to one expedient configuration, a protective layer is applied on both outer sides of the layer construction. The protective layer is here in general directly connected in each case to the electrode layer contacting the piezoceramic.

The bending transducer can here be characterized by different layer constructions. For example, the bending transducer can have for example only one piezoelectrically active element, that is to say one piezoactive material having electrode layers applied thereon on both sides, without further mechanical carrier layers and without further additional piezoelectrically active elements. Onto this single piezoelectrically active element, the protective layer is preferably applied on both sides. In a construction using a mechanical carrier layer, such as for a monomorph or else trimorph construction, the mechanical carrier in the present case is counted as being part of the layer construction. In a monomorph configuration, the mechanical carrier terminates the layer construction on one side. In this embodiment variant, the protective layer is preferably applied only on one side of the layer construction, that is to say on the side that is remote from the mechanical carrier, because the mechanical carrier typically exerts a sufficiently large stabilizing effect.

In a trimorph configuration, that is to say a configuration in which one piezoelectrically active element is applied on each side of a mechanical carrier and the layer construction is therefore composed of the mechanical carrier and two piezoelectrically active elements arranged on its two opposite sides, the protective layer is applied externally on the two outer sides of the layer construction, that is to say to the outermost sides of the piezoelectrically active element. In principle, the same is true if a plurality of piezoelectrically active elements are arranged on the mechanical carrier either on both sides or on one side, in the manner of stacks.

In a bimorph or multimorph configuration, where the layer construction is formed by a plurality of piezoelectrically active elements which are bonded to each other without a mechanical carrier, one electrical protective layer is preferably arranged again on each opposite outer side of the layer construction.

The bending transducer generally has what is referred to as a neutral zone, which is formed by a middle plane of the layer construction, which typically extends parallel to the layers of the layer construction. According to one preferred configuration, provision is made for the layer construction to be arranged asymmetrically with respect to the neutral zone of the bending transducer, that is to say for the middle plane of the layer construction to not coincide with the middle plane of the bending transducer. Preferably, provision is also made for the layer construction to be completely moved out of the neutral zone such that the neutral zone adjoins the layer construction on the outside, or is even arranged outside the layer construction. This configuration is of particular advantage, in particular when the bending transducer is used as a generator for the generation of energy, in order to be able to generate a meaningful amount of energy. According to one preferred configuration, provision is in this case made for the bending transducer to be used and mounted such that the bending transducer is loaded (bent) only in one direction, specifically in a manner such that the layer construction—since it is arranged outside the neutral zone of the bending transducer—is loaded only with pressure, because the piezoceramic is more resistant with respect to pressure loads.

According to one expedient configuration, this is achieved by an asymmetric configuration of the two protective layers, which are applied on the outside. The two protective layers thus differ in terms of their thickness in that the layer construction is offset with respect to the neutral zone, as compared to a symmetric construction. The thickness of the thicker protective layer is in this case preferably greater than or equal to the overall thickness of the layer construction and the thinner protective layer.

According to one preferred configuration, a laminated-on plastic film is used as an in particular elastic protective layer. This is in particular understood to mean attachment by adhesively bonding a commercially available lamination film, which is formed for example of PVC or another thermoplastic material. A plastic film of this type is laminated onto the layer construction, that is to say adhesively bonded thereto. Commercially available lamination films have for this purpose a special coating which becomes tacky upon the action of heat and thus forms an adhesive layer.

According to one preferred alternative, the protective layer is composed of a flexible printed-circuit-board material, for example what is referred to as FR3 or in particular the FR4 material. Such a printed-circuit-board material is typically composed of a cured epoxy resin. The FR4 material is a glass-fiber-reinforced epoxy resin. Such films of printed-circuit-board material are readily available on the market and in multifarious embodiment variants. The protective layer of this printed-circuit-board material is preferably also adhesively bonded to the layer construction.

Expediently, a number of conductor tracks or a conductive layer is/are applied directly onto the protective layer. In particular, the protective layer in this case is a carrier layer of a flexible printed-circuit board. This embodiment variant permits particularly simple and lastingly reliable electrical contacting of the piezoceramic or of the respective electrode layer applied on the piezoceramic. Contacting therefore occurs using this protective layer that is additionally applied on the outside. In this embodiment variant, in particular a conductive adhesive is used for connection to the layer construction, such that a conductive connection is established between the conductor tracks or the carrier layer and the electrode layer of the layer construction. However, the conductive connection can in any case also be established by using an extremely thin adhesive layer.

In particular when the bending transducer is configured as a carrier layer of a flexible printed-circuit board having conductor tracks arranged thereon, the entire bending transducer is configured as a pre-fabricated electromechanical device, which needs only be contacted and connected at contact points that are intended for this purpose and are in particular formed on the printed-circuit board. In principle, it is also possible to arrange further electronic devices or circuits directly on the flexible printed-circuit board. The flexible, in particular film-type, printed-circuit board forming the protective layer preferably projects at the edges over the layer construction and has, in the projecting partial region, a contact surface for contacting the bending transducer with a connection line.

The conductor tracks or the conductive layer is/are formed on the protective layer for example by way of methods which are known per se in particular from printed-circuit-board technology, such as sputtering, electroplating, adhesive bonding or roller-application.

According to one preferred development, the conductive layer, which is arranged directly on the protective layer, at the same time forms an electrode for the piezoelectric element, i.e. the conductive layer comes into contact directly with the piezoceramic, possibly using a conductive adhesive.

In a preferred configuration, the layer construction is arranged in the manner of a sandwich between two such printed-circuit-board films with integrated conductor tracks or with a conductive layer that is applied thereon. In particular, provision is furthermore made for the conductor tracks ending in connection surfaces or contact surfaces, at which, in the connected state, connection wires are contacted, preferably by way of soldering. According to one expedient development, the protective layers in this case project over the layer construction on alternating sides, and in the projecting partial region, the contact surfaces are formed, as a result of which simple contacting is made possible.

According to a third alternative configuration, the protective layer is formed by a varnish layer. A varnish layer in the present case is a layer which is formed by applying a suitable varnish, for example a synthetic resin varnish, in the viscous state onto the layer construction for example by spraying, brushing, rollers, and which cures on account of the evaporation of a solvent after application. In principle it is generally possible, in addition to the protective layer, to impregnate the piezoceramic additionally with a suitable varnish for improving the mechanical properties.

In a preferred configuration, the bending transducer is formed overall by arranging the protective layer such that the transducer is compressed at least to approximately 10% under a pressure load and/or elongated at least to approximately 1% under an elongation load, without being damaged. The bending transducer with the protective layer has therefore a noticeably stronger reversible load capacity than a bending transducer without the use of such a protective layer.

Expediently, the bending transducer is used as an actuator, as a sensor and in particular for the generation of energy as a generator. It is preferably used as a generator in a tire-pressure sensor for providing energy for wireless signal transmission.

Embodiment variants of the invention will be explained in more detail below with reference to the figures. Said figures show, in schematically and strongly simplified, partially detail-type illustrations:

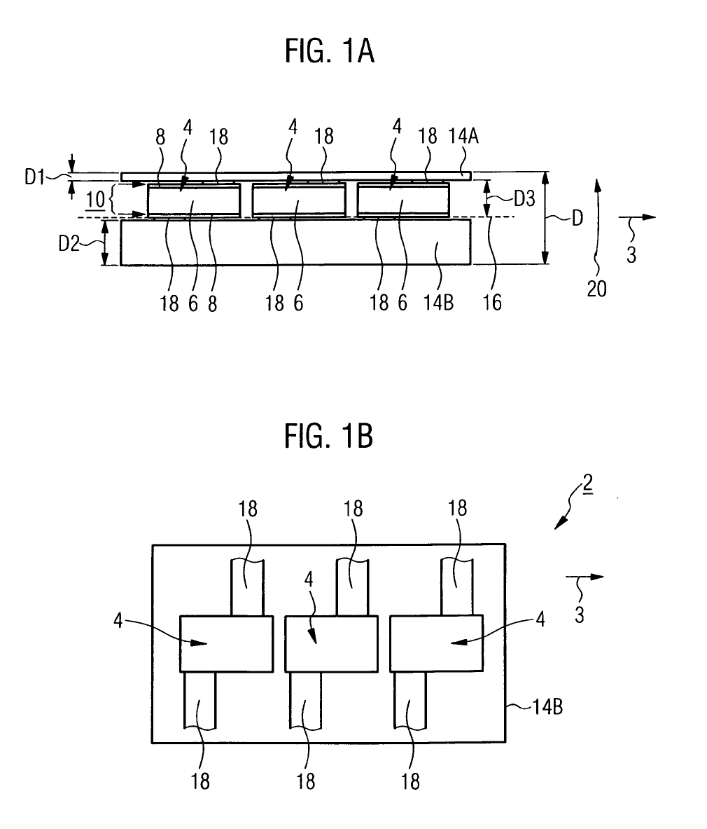

FIG. 1A shows a bending transducer in a side view,

FIG. 1B shows a plan view of the bending transducer as per FIG. 1A without the upper protective layer,

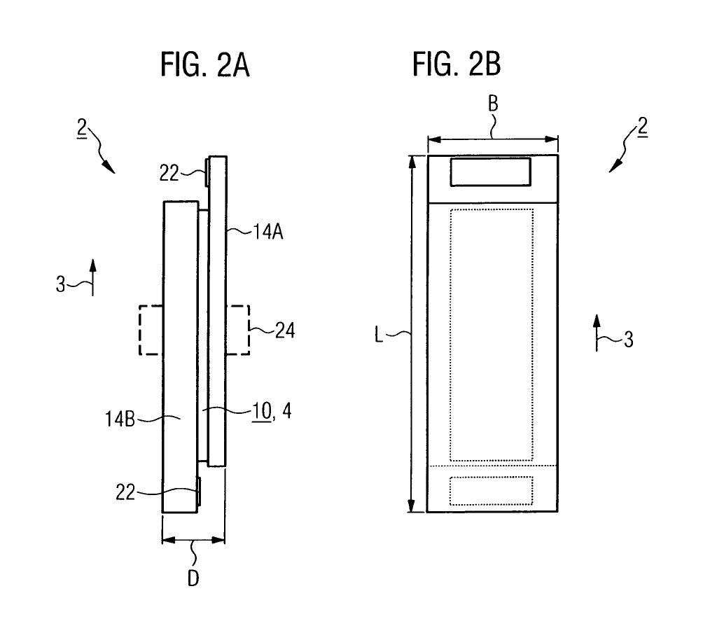

FIG. 2A shows a bending transducer of a further embodiment variant in a side view,

FIG. 2B shows a plan view of the bending transducer as per FIG. 2A,

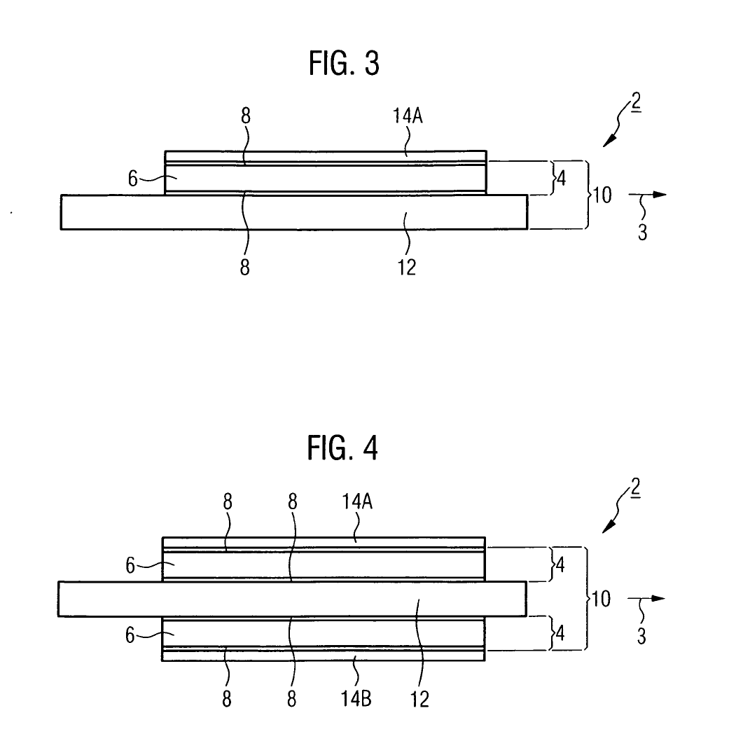

FIG. 3 shows a side view of a bending transducer in a monomorph configuration, and

FIG. 4 shows a side view of a bending transducer in a trimorph configuration.

In the figures, parts with the same function are followed by the same reference signs.

The various embodiment variants illustrated in the figures of bending transducers 2 extend in the longitudinal direction 3 and have in each case at least one piezoelectrically active element 4. The latter generally consists of a layer composed of a piezoactive material, in particular a piezoceramic 6 (preferably PZT ceramic). Electrode layers 8 are arranged on both sides of the piezoceramic 6. The piezoceramic 6 with the electrode layers 8 in each case form the piezoelectrically active element 4.

The piezoelectrically active element 4 forms, in the embodiment variants according to FIGS. 1A, 1B and 2A, 2B at the same time a layer construction 10. In the monomorph configuration illustrated in FIG. 3, the layer construction 10 is formed by a mechanical carrier 12, on whose one side the piezoelectrically active element 4 is arranged. In the trimorph embodiment variant according to FIG. 4, the layer construction 10 is formed by the mechanical carrier 12 and the piezoelectrically active elements 4 which are applied on both sides thereon. The mechanical carrier itself is basically known in various embodiment variants and is formed, for example, from an insulating material or from a conductive material, such as a metal, for example. In the configuration as a conductive element, the adjoining electrode layer 8 may be omitted. The thickness of the carrier 12 is typically greater than that of the piezoactive element 4 and typically ranges from 0.2 to 3 mm. The production of these different layer constructions 10 is known per se.

All the bending transducers 2 illustrated in the figures are distinguished by the additional arrangement of at least one for example elastic protective layer 14A, B, which is applied onto the layer construction 10 in particular under prestress. Said protective layer thus exerts a pressure or shear load within the bonding plane, at least in the orientation of the longitudinal direction 3. The force exerted by the prestress is therefore directed from an external region to a central region.

While in the monomorph configuration according to FIG. 3 only one protective layer 14A is applied on the outside of the layer construction 10, in the other embodiment variants in each case one protective layer 14A, 14B is applied on both opposite outer sides of the layer construction 10. The protective layers 14A, 14B are applied in this case preferably using a suitable adhesive, for example based on acrylates or epoxy resins. If appropriate, a conductive adhesive may also be used. The protective layers 14A, 14B preferably have a greater surface area than the layer construction 10, such that they overlap the layer construction edge-side in at least one direction.

Generally, the embodiment variants according to FIGS. 1A, 1B, 2A, 2B and FIG. 4 are distinguished in that the layer construction is arranged in an adhesively bonded fashion in the manner of a sandwich between two film-type protective layers.

In the embodiment variant according to FIGS. 1A, 1B, no continuous piezoelectrically active element is provided, but rather individual segments are arranged on piezoelectrically active elements 4 between the two protective layers 13A, 13B.

In FIG. 1A, a neutral zone 16 of the bending transducer 2 is additionally indicated by a dashed line. The neutral zone 16 is formed here by a central plane extending parallel to the individual layers, that is to say a central plane that has the same distance from the external flat sides of the bending transducer 2 which are formed by the external flat sides of the two protective layers 14A, 14B. As can be seen in FIG. 1A, the layer construction 10 is arranged asymmetrically with respect to this neutral zone and in particular is moved completely out of the neutral zone 16. In the exemplary embodiment, the layer construction 10 directly adjoins the neutral zone 16.

In the exemplary embodiment, this is achieved by a different thickness of the two protective layers 14A, 14B. The upper protective layer 14A here has a considerably lower thickness D1 as compared to the thickness D2 of the lower protective layer 14B. In the exemplary embodiment, the thickness D2 equals the sum of the thickness D1 and the thickness D3 of the layer construction 10. Typically, the thickness D3 for the layer construction 10 when only one piezoceramic 6 layer is used ranges for example from 50 to approximately 500 μm. The electrode layers 8 applied on both sides of the piezoceramic 6 have in each case a thickness which can vary depending on the configuration of the electrode layer and is, for example when gold electrodes are used, a few 100 nm. When carbon electrodes are used, the thickness of the electrode layer is for example 5 to 50 μm. Carbon electrodes are generally understood to mean electrodes made from a carbon polymer, in which a heat-curing resin (e.g. epoxy resin) with graphite as additional embedded pigment particles is applied.

The protective layers 14A, 14B are preferably formed from a printed-circuit-board material, for example the material known as FR4 material. The latter is a glass-fiber-reinforced cured epoxy resin. The thickness of the protective layers 14A, 14B is preferably greater than 100 μm. In the exemplary embodiment, for example a layer construction 10 with a thickness D3 in the range of 200 to 500 μm and an upper protective layer 14A with a thickness D1 in the range of 100 to 200 μm is used. The thickness D2 of the lower protective layer 14B is then in the range from 400 to 700 μm.

Conductive regions in the manner of conductor tracks 18 are applied onto the protective layers 14A, 14B in the exemplary embodiment of FIGS. 1A, 1B. The protective layer 14A, 14B together with the conductor tracks 18 forms a film-type flexible printed-circuit board. The protective layers 14A, 14B are in this case the carrier layers of said flexible printed-circuit boards, on which the conductor tracks 18 are applied. Contacting of the individual electrode layers 8 takes place in a particularly simple and efficient manner via the conductor tracks 18. It is therefore possible in a simple manner via the printed-circuit boards and the conductor tracks 18 thereof for the transmission of the electric signals (electric charge carriers) generated in a mechanical deformation to take place. The contacting of the individual conductor tracks 18 for transmission to a control unit connected downstream or to an energy store in this case takes place via contacts (not shown in more detail here), which are formed for example by widened contact surfaces of the contact tracks 18, on which for example connecting wires are soldered etc. In the plan view according to FIG. 1B, the connection possibilities of the conductor tracks 18 are not illustrated. These are illustrated only schematically by outgoing conductor tracks 18 (illustrated only partially).

For the configuration of the lower protective layer 14B with the large thickness D2, it is also possible for a plurality of plies of individual films of the protective layers to be arranged one on top of the other. Such a bending transducer as is illustrated in FIG. 1A is clamped in a holding device for example at one end side, for example at its left end, while the opposite, right end forms a free end. The latter is deflected in the installed state preferably only in a bending direction indicated by the arrow 20, so that the individual piezoelectric elements 4 are loaded only by pressure.

The exemplary embodiment according to FIGS. 2A, 2B largely corresponds to the exemplary embodiment according to FIGS. 1A, 1B. In this case, too, the bending transducer 2 is formed by two opposite protective layers 14A, 14B of different thickness with a (single) piezoelectric element 4 arranged therebetween. The protective layers 14A, 14B project—as in the exemplary embodiment of FIGS. 1A and 1B—the piezoelectric element 4. In the variant according to FIGS. 2A, 2B, the protective layers 14A, 14B project over the piezoelectric element 4 in the longitudinal direction of the bending transducer 2 so far that the two protective layers 14A, 14B are arranged offset in the longitudinal direction and have a projecting region with respect to each other. In these projecting regions, contact surfaces 22 are formed on the inner sides of the protective layers 14A, 14B, on which contact surfaces for example a connecting wire is soldered. Provision is preferably made in this case, too, for the protective layers 14A, 14B to be provided with conductor tracks 18 (not illustrated in further detail) for contacting the electrode layers 8 (also not illustrated in further detail).

In FIG. 2A, approximately centrally in the region of the bending transducer, a possible mounting location 24 is indicated by a dashed line, in which the bending transducer 2 is clamped for example in its mounted end position. FIG. 2B shows a view, which is rotated about 90° with respect to FIG. 2A, without the mounting location 24. The width B of a bending transducer 2 is generally typically in the range between 3 and 10 mm, and in the exemplary embodiment for example 5.5 mm. The length L of a typical bending transducer 2 is for example in the range of 20 to 50 mm and in the exemplary embodiment for example approximately 30 mm. The overall thickness D of a typical bending transducer is for example in the range of 400 to 1500 μm, and in the exemplary embodiments according to FIGS. 1A and 2A in the range of approximately 650 μm.

In the exemplary embodiments shown in the figures, in each case the protective layer 14A, 14B is applied on the outside onto the layer construction 10 with the electrode layers 8 as an additional layer with conductor tracks 18 which are applied thereto. In one alternative embodiment variant, provision is made for a conductive layer to be applied on the protective layers 14A, 14B which form the electrode layers 8.

All the exemplary embodiments are distinguished by the use of a protective layer 14A, 14B, wherein preferably the layer construction 10 is arranged in an adhesively bonded fashion between two protective layers 14A, 14B. With this measure, the load capacity of the layer construction is significantly increased and the risk of breaking is reduced. Overall considerably higher bending stresses of the bending transducer 2 are made possible by this measure.

A further special design feature is considered to be that the piezoelectrically active layer construction 10 is moved out of the neutral zone 16 of the bending transducer 2 in order to make possible a meaningful energy generation for a generator operation. Furthermore, the arrangement of the conductor tracks 18 or a conductive layer directly on the protective layer 14A, 14B in particular to complement the electrode layer 8 arranged on the piezoceramic 6 should be emphasized. This is because a particularly simple contacting of the electrode layers 8 is made possible by the conductor tracks 18. Overall, a bending transducer 2 with a high load capacity is thus formed, which has contacting that is realizable in a simple manner and functions reliably even at high bending stresses. In particular in a configuration, in which a conductive layer, applied onto the protective layers 14A, 14B, itself forms the electrode layer (or is provided in addition to the electrodes 8), particularly robust contacting is possible. This is because even in the case of a possible tear of the piezoceramic 6, the latter is still reliably contacted over the full area, without parts of the surfaces of the piezoceramic 6 remaining uncontacted. The conductor tracks 18 or conductive layers are produced for example by sputtering, printing or laminating with conductive materials, such as silver, gold, carbon or copper.

### LIST OF REFERENCE SIGNS

2 bending transducer
3 longitudinal direction
4 piezoelectrically active element
6 piezoceramic
8 electrode layer
10 layer construction
12 mechanical carrier
14A, B protective layer
16 neutral zone
18 conductor track
20 bending direction
22 contact surface
24 mounting location
B width
D1 thickness
D2 thickness
D3 thickness
L length

1-18. (canceled)

19. A bending transducer, comprising:
a layer construction containing a piezoelectrically active element formed of a piezoactive material and electrode layers applied on said piezoactive material;
contact surfaces; and
a protective layer having two films and disposed on an outer side of said layer construction, said layer construction disposed in a manner of a sandwich between said two films forming said protective layer, said two films overlapping on an edge-side over said layer construction and have in each case conductor tracks on an inner side facing said layer construction, via said conductor tracks said piezoelectric element is contacted, and said protective layer having said contact surfaces disposed in an overlapping partial region and on which in a connected state a connection line is contacted.

20. The bending transducer according to claim 19, wherein said protective layer is applied onto said layer construction under a prestress.

21. The bending transducer according to claim 19, wherein said protective layer has a coefficient of thermal expansion that is greater than that of said layer construction.

22. The bending transducer according claim 19, wherein said protective layer has a higher elasticity and/or a higher modulus of elasticity than said layer construction.

23. The bending transducer according to claim 19, wherein said protective layer has a thickness greater than 50 μm.

24. The bending transducer according to claim 19, further comprising neutral zone, said layer construction is disposed asymmetrically with respect to said neutral zone.

25. The bending transducer according to claim 24, wherein said two films having thicknesses which differ, such that said layer construction is asymmetrical with respect to said neutral zone on account of the different thicknesses of said two films of said protective layer.

26. The bending transducer according to claim 25, wherein a thickness of a thicker one of said two films is greater than or equal to an overall thickness of said layer construction and a thinner one of said two films of said protective layer.

27. The bending transducer according to claim 19, wherein said protective layer is a laminated-on plastic film.

28. The bending transducer according to claim 19, wherein said protective layer is composed of a flexible printed-circuit-board material.

29. The bending transducer according to claim 19, further comprising a conductive layer applied onto said protective layer, wherein said protective layer is a carrier layer of a flexible printed-circuit board.

30. The bending transducer according to claim 29, wherein said conductive layer forms an electrode of said piezoelectric element.

31. The bending transducer according to claim 19, wherein said two films of said protective layer project over said piezoelectric element with different lengths, wherein in projecting regions thus formed said contact surfaces are disposed.

32. The bending transducer according to claim 19, wherein said protective layer is formed by a varnish layer.

33. The bending transducer according to claim 19, wherein the bending transducer can be compressed at least to approximately 10% under a pressure load and/or elongated at least to approximately 1% under an elongation load, without being damaged.

34. The bending transducer according to claim 19, wherein the bending transducer functions as one of an actuator, a sensor and a generator for energy generation.

35. The bending transducer according to claim 19, wherein said protective layer has a thickness ranging from 50 μm to 1000 μm.
